(19) United States
(12) Patent Application Publication
(10) Pub. No.: US 2020/0332163 A1
(43) Pub. Date: Oct. 22, 2020

(54) POLISHING LIQUID AND METHOD FOR PRODUCING POLISHED ARTICLE

(71) Applicant: MITSUI MINING & SMELTING CO., LTD., Tokyo (JP)

(72) Inventors: Ken MATSUO, Fukuoka (JP); Masayuki MATSUYAMA, Fukuoka (JP); Akinori KUMAGAI, Fukuoka (JP)

(73) Assignee: Mitsui Mining & Smelting Co., Ltd., Tokyo (JP)

(21) Appl. No.: 16/305,266

(22) PCT Filed: May 29, 2017
(86) PCT No.: PCT/JP2017/019901

§ 371 Date: Nov. 28, 2018

(30) Foreign Application Priority Data
Jun. 8, 2016 (JP) 2016-114160

(51) Int. Cl. C09K 3/14; C09G 1/02; H01L 21/304

(52) U.S. Cl. CPC C09K 3/1463; C09K 3/1445; H01L 21/304; C09G 1/02

(57) ABSTRACT

A polishing liquid contains permanganate ions, a weak acid, and a soluble salt of the weak acid. The polishing liquid preferably has a pH of 0.5 to 6.0 at 25° C. before commencement of polishing. When a 0.1 mol/L aqueous solution of sodium hydroxide is added to 100 mL of the polishing liquid having been adjusted to pH 3.0 to 4.0 at 25° C., the amount of the sodium hydroxide aqueous solution necessary to raise the pH of the polishing liquid by 0.5 is preferably 0.1 to 100 mL. The weak acid is preferably acetic acid.

### CROSS-REFERENCE TO RELATED APPLICATIONS

This application is a U.S. National Stage Application of International Application No. PCT/JP2017/019901, filed on May 29, 2017, and claims priority to Japanese Patent Application No. 2016-114160, filed on Jun. 8, 2016. The entire disclosures of the above applications are expressly incorporated herein by reference.

### BACKGROUND

### Technical Field

This invention relates to a polishing liquid containing permanganate ions and a method for providing a polished substrate using the same.

### Related Art

In the field of power semiconductor devices, also called power devices, which are a type of semiconductor devices, it has been proposed to use, in place of a conventional silicon substrate, a silicon carbide, gallium nitride, diamond, or like substrate for the purpose of coping with the trends toward high voltage and high current. The substrates composed of these materials other than silicon withstand high voltages because of large band gaps as compared with the silicon substrate. The high-voltage resistance characteristics of the substrates composed of silicon carbide, gallium nitride, and so on are considered attributed to the denser arrangement of the constituent atoms than that of silicon.

On the other hand, silicon carbide, gallium nitride, or like substrates are so hard that they are very difficult to polish with existing abrasives. Silicon carbide and so on are particularly hard due to the dense atomic arrangement as stated above. For example, the Mohs hardness of silicon carbide and gallium nitride is about 9, and that of diamond is 10. However, if polished with diamond, such a hard substrate undergoes only mechanical polishing and tends to suffer a defect or distortion, making the resulting device less reliable. This tendency increases with an increase in hardness.

To address the above problem, various techniques have so far been proposed with a view to increasing the polishing efficiency of hard materials.

For instance, US 2010/114149 A discloses an aqueous CMP composition containing a particulate silica abrasive in a concentration of about 0.1 to 5 wt % and an acidic buffering agent providing a pH in the range of about 2 to 7. US 2010/114149 A describes the aqueous CMP composition containing abrasive grains and an acidic buffering agent as achieving an increased removal rate selectivity for silicon carbide versus silicon dioxide.

JP 2014-168067 A discloses a method for polishing a non-oxide single crystal substrate, in which the surface to be polished of a non-oxide single crystal substrate is brought into contact with a polishing pad and polished by relative movement between the substrate and the polishing pad while suppling a polishing liquid containing permanganate ions and water to the pad. The method comprises recovering the polishing liquid having been supplied to the pad and used for polishing, supplying the recovered polishing liquid to the pad thereby to recirculate the polishing liquid, and adjusting the pH of the polishing liquid while being used to polish the surface to 5 or lower. The method is described as capable of maintaining a high polishing rate over an extended polishing time.

According to the method of polishing without use of permanganate ions and a weak acid salt as disclosed in US 2010/114149 A, the aqueous CMP composition does not achieve a sufficient polishing rate. Furthermore, US 2010/114149 A neither describes nor suggests an approach to preventing reduction of polishing rate when polishing is continued over a long period of time while repeatedly recycling the polishing composition.

The method of JP 2014-168067 A has the problem of labor and cost for managing the equipment and polishing liquid.

An object of the invention is to provide a polishing liquid and a method for providing a polished substrate, by which various disadvantages associated with the above described conventional techniques are eliminated.

### SUMMARY

The invention provides a polishing liquid containing permanganate ions, a weak acid, and a soluble salt of the weak acid.

The invention also provides a method for providing a polished substrate comprising using the polishing liquid of the invention.

### BRIEF DESCRIPTION OF THE DRAWINGS

FIG. 1 is a graph showing changes in pH of the polishing liquid with time in Comparative Examples 1 and 2 and Example 1.

FIG. 2 is a graph showing changes in pH of the polishing liquid with time in Comparative Example 3 and Example 2.

FIG. 3 is a graph showing changes in pH of the polishing liquid with time in Comparative Example 4 and Example 3.

### DETAILED DESCRIPTION OF THE PREFERRED EMBODIMENTS

The invention will be described on the basis of its preferred embodiment, which relates to a polishing liquid containing permanganate ions and, in addition, a weak acid and a soluble salt thereof.

A permanganate ion (MnO₄⁻) is supplied from a permanganate. Examples of the permanganate include alkali metal salts, alkaline earth metal salts, and an ammonium salt of per manganic acid. Preferred permanganates as a permanganate ion (MnO₄⁻) source are alkali metal permanganates in terms of availability and improvement in polishing efficiency of the polishing liquid of the embodiment. Sodium permanganate and potassium permanganate are particularly preferred. The permanganates described may be used either individually or as a mixture of two or more thereof.

With the view of sufficiently enhancing the inhibitory effect on reduction of polishing rate, the concentration of the permanganate ions (MnO₄⁻) in the polishing liquid is preferably 0.1 mass % or higher. The permanganate ion (MnO₄⁻) concentration is more preferably 20.0 mass % or lower with a view to securing the safety in handling the polishing liquid and in view of the tendency of the polishing rate to plateau even if the concentration is more increased. From these considerations, the permanganate ion (MnO₄⁻) concentration in the polishing liquid is preferably 0.1 to 20.0 mass %, more preferably 0.2 to 10 mass %, even more preferably 0.5 to 5 mass %. The permanganate ion (MnO₄⁻) concentration can be measured by ion chromatography or absorptiometry. The term “concentration (or amount or content)” as used herein with respect to a component of a polishing liquid refers to the concentration (or amount or content) of the component in the polishing liquid before commencement of polishing unless otherwise specified.

The polishing liquid of the embodiment contains a weak acid and its soluble salt, whereby reduction in polishing rate is prevented, and a high polishing rate is retained even when the polishing liquid is used repeatedly for a long time. The inventors have investigated polishing of hard materials, such as silicon carbide and gallium nitride, with a polishing liquid containing permanganate ions and found that the polishing rate is high in the initial stage of polishing but drastically decreases with the progress of polishing and that this phenomenon is particularly conspicuous when the permanganate ion concentration is high. As a result of further study on a method for preventing such a drastic reduction of polishing rate, they have found that the drastic reduction in polishing rate is effectively prevented by the use of a weak acid and its soluble salt.

As used herein, the term “weak acid” refers to an acid having a small acid dissociation constant pKa, preferably a pKa of 1.0 or greater at 25° C. In the case of a polybasic acid, the term “pKa” as used herein means a pKa1. The pKan (where n is any integer greater than one) of a polybasic acid for use in the invention is preferably 3.0 or greater. Examples of acids with a pKa of 1.0 or greater include organic acids having a carboxyl group, such as acetic acid, phosphoric acid, formic acid, butyric acid, lauric acid, lactic acid, malic acid, citric acid, oleic acid, linoleic acid, benzoic acid, oxalic acid, succinic acid, malonic acid, maleic acid, and tartaric acid; and inorganic acids, such as boric acid, hypochlorous acid, hydrogen fluoride, and hydrosulfuric acid. Among them organic acids having a carboxyl group are preferred. In particular, the effect of the combination of permanganate ions, a weak acid, and a soluble salt of the weak acid in preventing reduction of polishing rate in a prolonged polishing operation is particularly high when acetic acid, phosphoric acid, or forming acid is used. Inter alia, acetic acid is preferred in terms of cost and performance. These weak acids may be used either individually or in combination thereof.

The soluble salt of the weak acid is exemplified by a neutralization salt with a strong base, such as an alkali metal salt or an alkaline earth metal salt. An alkali metal salt is preferred from a viewpoint of availability and solubility. From the same viewpoint, a sodium salt and/or a potassium salt are more preferred. A sodium salt is the most preferred. These soluble salts may be used either individually or in combination. In the present embodiment, it is preferred for the soluble salt to have a solubility of at least 1.0 g, more preferably 10 g or more, per 100 mL of water at 25° C.

It is not clear why incorporation of a weak acid and its soluble salt prevents drastic reduction in polishing rate, but the inventors believe that the reason for this may be as follows. When a polishing liquid containing permanganate ions but not containing a weak acid and its soluble salt is acidic, according as polishing proceeds, the surface being polished undergoes excessive oxidation by the permanganate ions. The oxidation reaction by the permanganate ions under an acidic condition is represented by ionic equation (1) below. Occurrence of the excessive oxidation reaction indicates that the equilibrium in ionic equation (1) suddenly shifts to the right.

MnO₄⁻+8H⁺+5e⁻⇔Mn²⁺+4H₂O (1)

The inventors considered that the drastic reduction in polishing rate is caused by the excessive occurrence of the reaction according to ionic equation (1) and intensively studied on a method for suppressing this phenomenon. The inventor surmised that the phenomenon would be suppressed by incorporating a weak acid and its soluble salt into a polishing liquid.

When a polishing liquid contains a weak acid and its soluble salt as well as permanganate ions, the following dissociation reactions take place in the polishing liquid. In the following ionic equations, HA is a weak acid; H⁺ is a hydrogen ion; A⁻ is the anion of the weak acid; BA is a soluble salt of the weak acid; and B⁺ is the cation of the soluble salt.

HA⇔H⁺+A⁻ (2)

BA⇔B⁺+A⁻ (3)

The dissociation of the weak acid HA as represented by equation (2) is usually suppressed because of the existence of a given amount of the A⁻ ion in the polishing liquid as a result of the dissociation of the soluble salt BA as represented by equation (3). The inventors assumed that the permanganate ions would be prevented from excessively occurring by controlling the hydrogen ion quantity in the polishing liquid by the presence of a weak acid and its soluble salt. Based on this assumption, they actually performed polishing using a polishing liquid containing permanganate ions in the presence of a weak acid and its soluble salt and confirmed that the rise in pH of the polishing liquid was gradual with the progress of polishing and, at the same time, reduction in polishing rate is effectively prevented. When plotting pH of the polishing liquid as the ordinate and polishing time as the abscissa, in the case where the polishing liquid is acidic and contains neither a weak acid nor its soluble salt, the pH suddenly increases with time in the initial stage, and then the pH rise becomes gradual with further elapse of time. Thus, in that case, the plot of pH as ordinate and time as abscissa exhibits two straight line segments—a straight line segment steeply sloping upward up to pH 7 to 8 and a subsequent straight line segment gently sloping upward—connected via a kink.

In contrast, on the condition that the initial pH is 6 or less, the pH of the polishing liquid of the embodiment rises with time at a gentle slope up to pH 7 to 8 and even thereafter shows little change in slope with further elapse of time as compared with a polishing liquid containing neither a weak acid nor a soluble salt thereof. That is, the slope of pH rise of the polishing liquid of the embodiment is gentler up to pH 7 to 8 and is less likely to change even thereafter with further elapse of polishing time than that of the polishing liquid containing neither a weak acid nor its soluble salt. Therefore, the polishing liquid of the embodiment shows an almost linear plot of pH change vs. time. The inventors have thus revealed that reduction in polishing rate is effectively prevented when the rise in pH is controlled to be gradual.

In the embodiment the total amount of the weak acid and its soluble salt in the polishing liquid is preferably such that satisfies the hereinafter described pH range and buffering capacity of the polishing liquid. Specifically, the total number of moles of the weak acid anion is preferably 0.001 mol/L or more with the view of effectively preventing early reduction in polishing rate and preferably 1 mol/L or less in view of ease of use of the polishing liquid and with a view to preventing odor generation, more preferably 0.01 to 0.1 mol/L.

The total amount of the weak acid and its soluble salt in the polishing liquid is obtained by, for example, converting all the weak acid to its soluble salt and determining the weak acid concentration by potentiometric titration.

With the view of effectively preventing reduction in polishing rate, the amount of the soluble salt of the weak acid in the polishing liquid is preferably 0.05 to 20 mol, more preferably 0.1 to 10 mol, per mole of the weak acid.

The amount of the soluble salt in the polishing liquid can be determined by, for example, potentiometric titration.

In order to accelerate the reaction of permanganate ions represented by ionic equation (1) thereby to achieve efficient polishing, the polishing liquid before commencement of polishing is preferably acidic. For this reason, the pH of the polishing liquid before commencement of polishing is preferably 6 or lower, more preferably 5 or lower, even more preferably 4 or lower, at 25° C. The pH of the polishing liquid before commencement of polishing is preferably 0.5 or higher, more preferably 1.0 or higher, even more preferably 1.5 or higher, at 25° C. in terms of handling safety and control of hydrogen ion in the polishing liquid.

It is preferred for the polishing liquid of the embodiment to have high pH buffering capacity with a view to effectively suppressing excessive progress of the oxidation reaction of permanganate ions, thereby preventing rapid reduction in polishing rate. As used herein, the term “buffering capacity” refers to an index obtained as the amount of a 0.1 mol/L aqueous solution of sodium hydroxide necessary to raise the pH of 100 mL of a polishing liquid having been adjusted to pH 3.0 to 4.0 at 25° C. by 0.5. The buffering capacity of the polishing liquid of the embodiment as defined above is preferably 0.1 to 100 mL, more preferably 1.0 to 50 mL, even more preferably 2.0 to 10 mL.

The pH of the polishing liquid to be tested for buffering capacity may be adjusted by the addition of a 0.1 mol/L aqueous sodium hydroxide solution when it is lower than 3.0, or by the addition of a 0.05 mol/L diluted sulfuric acid when it is higher than 4.0. It suffices for the polishing liquid to have the above defined buffering capacity falling within the above range at any pH value in the range of from 3 to 4. The above described preferred buffering capacity does not need to be satisfied at pH values out of the range of from 3 to 4.

The polishing liquid of the embodiment may or may not contain abrasive particles. Seeing that the polishing liquid of the embodiment retains a high level of polishing performance owing to the strong oxidative power of permanganate ions even after long-term repeated use, it exhibits high polishing performance without abrasive particles. The absence of abrasive particles is advantageous in terms of eliminating the risk of the buffering capacity of the polishing liquid against pH change causing some types of abrasive particles to form agglomerates that can damage the surface being polished. On the other hand, the presence of abrasive particles in the polishing liquid of the embodiment favors increasing the polishing rate, thereby enhancing the inhibitory effect on the reduction of polishing rate during repeated use in a circulatory system. Examples of suitable particulate abrasive materials include alumina, silica, manganese oxide, cerium oxide, zirconium oxide, iron oxide, silicon carbide, and diamond. Manganese oxide includes manganese (II) oxide (MnO), dimanganese (III) trioxide (Mn₂O₃), manganese (IV) dioxide (MnO₂), and trimanganese (II, III) tetroxide (Mn₃O₄). Any known species of cerium oxide, zirconium oxide, and iron oxide may be used. These abrasives may be used either individually or in combination thereof.

Of these abrasives preferred are silica, manganese dioxide, and alumina in terms of enhancing the inhibitory effect of the use of a weak acid and its soluble salt on the reduction in polishing rate.

With a view to obtaining stable polishing performance, the abrasive preferably have an average particle size of 0.01 to 3.0 μm, more preferably 0.05 to 1.0 μm. The term “average particle size” as used herein with respect to the metal oxide abrasive particles refers to a diameter at 50% cumulative volume of particle size distribution (D₅₀) as determined by the laser diffraction method. Specific procedures for obtaining the average particle size will be described in Examples given later.

In the case where the polishing liquid of the embodiment contains an abrasive, the content of the abrasive in the polishing liquid is preferably 0.001 to 50 mass %, more preferably 0.01 to 30 mass %, even more preferably 0.1 to 10 mass %, with a view to increasing the removal rate of a hard material, securing appropriate flowability of the abrasive particles in the polishing liquid, and preventing agglomeration of the particles.

The polishing liquid of the embodiment may contain a specific inorganic compound in addition to permanganate ions, a weak acid, and a soluble salt of the weak acid. The specific inorganic compound is such that is able to increase a redox potential of a 1.0 mass % aqueous solution of the permanganate which is present in the polishing liquid when added thereto in an amount of 1.0 mass % relative to the permanganate aqueous solution. Such an inorganic compound is believed to accelerate the oxidation of a hard material with permanganate ions thereby to improve the polishing rate. The redox potential is measured at 25° C. using a silver/silver chloride electrode as a reference electrode according to the method described in Examples given later.

The specific inorganic compound is preferably such that increases the redox potential by 10 mV or more, more preferably 30 mV or more, even more preferably 50 mV or more, when added to the 1.0 mass % aqueous permanganate solution in the above described concentration. From the standpoint of availability of the inorganic compound and material cost, the specific inorganic compound is preferably such that produces a redox potential difference of 700 mV or less between before and after the addition. The redox potential of a 1.0 mass % aqueous solution of potassium permanganate at 25° C. before the addition of the inorganic compound is usually about 770 mV.

Examples of the inorganic compound that is able to increase the redox potential of a 1.0 mass % aqueous solution of the permanganate when added thereto in an amount of 1.0 mass % relative to the permanganate aqueous solution include nitric acid, inorganic nitrates, transition metal salts, iron-containing complexes, and peroxo acid salts. All these inorganic compounds are capable of increasing the redox potential of a 1.0 mass % aqueous solution of the permanganate when added thereto in a concentration of 0.01 mass % or more. The influence of the inorganic compound on the redox potential of the permanganate aqueous solution is made more conspicuous by increasing the amount of the inorganic compound added to the permanganate aqueous solution up to 1.0 mass %.

Examples of the inorganic nitrates include metal nitrates and metal nitrate complexes. The metal nitrates are exemplified by those represented by general formula: M(NO₃)ₐ, wherein M is a metal element; and a is the same number as the valence of the metal M. The valence of the metal M may be, but not limited to, the one when the metal acts as an oxidizer (electron acceptor). For example, when M is iron or cerium, the valence is 3 or 4, respectively, but iron may be divalent, or cerium may be trivalent.

The metal nitrate complexes are exemplified by amine complexes. Amine complexes of metal nitrates are represented by general formula: (NH₄)ₚ[M(NO₃)_{q}], wherein M is a metal element; q is 4 or 6; p is a number satisfying equation: p=q−b; and b is the valence of the metal M. The valence of the metal M may be, but not limited to, the one when the metal acts as an oxidizer (electron acceptor).

The inorganic nitrates are preferably those containing a transition metal. Examples of transition metal-containing inorganic nitrates include transition metal nitrates and transition metal nitrate complexes. Examples of the transition metal in the transition metal nitrates and transition metal nitrate complexes include rare earth elements, such as scandium (Sc), yttrium (Y), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu); iron group elements, such as iron (Fe), nickel (Ni), and cobalt (Co); and copper group elements, such as copper (Cu). Preferred of them are rare earth elements, especially cerium (Ce), in terms of ready availability and the high effect on improving the polishing rate when added as a specific additive.

Examples of suitable metal nitrates include rare earth nitrates, such as scandium nitrate (Sc(NO₃)₃), yttrium nitrate (Y(NO₃)₃), lanthanum nitrate (La(NO₃)₃), cerium nitrate (Ce(NO₃)₃), praseodymium (Pr(NO₃)₃), neodymium (Nd(NO₃)₃), samarium nitrate (Sm(NO₃)₃), europium nitrate (Eu(NO₃)₃), gadolinium nitrate (Gd(NO₃)₃), terbium nitrate (Tb(NO₃)₃), dysprosium nitrate (Dy(NO₃)₃), holmium nitrate (Ho(NO₃)₃), erbium nitrate (Er(NO₃)₃), thulium nitrate (Tm(NO₃)₃), ytterbium nitrate (Yb(NO₃)₃), and lutetium nitrate (Lu(NO₃)₃); iron group nitrates, such as iron (II) nitrate (Fe(NO₃)₂), iron (III) nitrate (Fe(NO₃)₃), nickel nitrate (Ni(NO₃)₂), cobalt (II) nitrate (Co(NO₃)₂), and cobalt (III) nitrate (CO(NO₃)₃); and copper group nitrates, such as copper (II) nitrate (Cu(NO₃)₂) and copper (III) nitrate (Cu(NO₃)₃). Rare earth nitrates are particularly preferred of them. Examples of suitable metal nitrate complexes include cerium (IV) ammonium nitrate ((NH₄)₂[Ce(NO₃)₆]). They may be either anhydrous or aqueous. As used herein, the terms “metal nitrate(s)” and “metal nitrate complex(es)” include those having changed their valence to take on a different form as a result of oxidation by the permanganate in the polishing liquid.

The transition metal salts other than nitrates include transition metal halides, such as fluorides, chlorides, bromides, and iodides; transition metal sulfates; and transition metal acetates. Preferred of them are transition metal chlorides and transition metal sulfates. The valence of the transition metal of the salts other than nitrates may be, but not limited to, the one when the transition metal acts as an oxidizer (electron acceptor). Examples of the transition metal of the chlorides and sulfates are the same as those recited above. Examples of suitable transition metal chlorides include rare earth chlorides, such as scandium chloride (ScCl₃), yttrium chloride (YCl₃), lanthanum chloride (LaCl₃), cerium chloride (CeCl₃), praseodymium chloride (PrCl₃), neodymium chloride (NbCl₃), samarium chloride (SmCl₃), europium chloride (EuCl₃), gadolinium chloride (GaCl₃), terbium chloride (TbCl₃), dysprosium chloride (DyCl₃), holmium chloride (HoCl₃), erbium chloride (ErCl₃), thulium chloride (TmCl₃), ytterbium chloride (YbCl₃), and lutetium chloride (LuCl₃); iron group chlorides, such as iron (II) chloride (FeCl₂), iron (III) chloride (FeCl₃), nickel chloride (NiCl₂), cobalt (II) chloride (CoCl₂), and cobalt (III) chloride (CoCl₃); and copper group chlorides, such as copper (II) chloride (CuCl₂) and copper (III) chloride (CuCl₃). Examples of suitable transition metal sulfates include rare earth sulfates, such as scandium sulfate (Sc(SO₄)₃), yttrium sulfate (Y(SO₄)₃), lanthanum sulfate (La(SO₄)₃), cerium (III) sulfate (Ce₂(SO₄)₃), cerium (IV) sulfate (Ce(SO₄)₂), praseodymium sulfate (Pr(SO₄)₃), neodymium sulfate (Nb(SO₄)₃), samarium sulfate (Sm(SO₄)₃), europium sulfate (Eu(SO₄)₃), gadolinium sulfate (Ga(SO₄)₃), terbium sulfate (Tb(SO₄)₃), dysprosium sulfate (Dy(SO₄)₃), holmium sulfate (Ho(SO₄)₃), erbium sulfate (Er(SO₄)₃), thulium sulfate (Tm(SO₄)₃), ytterbium sulfate (Yb(SO₄)₃), and lutetium sulfate (Lu(SO₄)₃); iron group sulfates, such as iron (II) sulfate (Fe(SO₄)₂), iron (III) sulfate (Fe(SO₄)₃), nickel sulfate (Ni(SO₄)₃), cobalt (II) sulfate (Co(SO₄)₂), and cobalt (III) sulfate (Co(SO₄)₃); and copper group sulfates, such as copper (II) sulfate (Cu(SO₄)₂) and copper (III) sulfate (Cu(SO₄)₃). These transition metal salts may be either anhydrous or aqueous. As used herein, the term “transition metal salts other than nitrates” includes those having changed their valence to take on a different form as a result of oxidation by the permanganate.

The iron-containing complexes are exemplified by ferricyanides, such as potassium ferricyanide (K₃[Fe(CN)₆]) and sodium ferricyanide (Na₃[Fe(CN)₆]. The peroxo acid salts are exemplified by percarbonates, perborates, and persulfates.

Persulfates are peroxo acid salts preferred in terms of further improving polishing rate of the polishing liquid of the embodiment. Alkali metal persulfates are more preferred. Potassium peroxodisulfate (K₂S₂O₈) or sodium peroxodisulfate (Na₂S₂O₈) is even more preferred.

Preferred of the above described inorganic compounds is nitric acid or a transition metal-containing inorganic nitrate; for the polishing liquid of the embodiment which contains it exhibits improved polishing rate for hard materials for a further prolonged period of time.

With a view to enhancing the improving effects of the inorganic compound on polishing rate and oxidative power per unit amount, the content of the inorganic compound in the polishing liquid is preferably 0.01 to 10.0 mass %, more preferably 0.02 to 4.0 mass %, even more preferably 0.05 to 2.0 mass %. When, in particular, the polishing liquid of the embodiment contains the transition metal-containing inorganic nitrate as the inorganic compound, the content of the inorganic nitrate in the polishing liquid is preferably 0.02 to 1.0 mass %, more preferably 0.05 to 0.5 mass %. The content of the inorganic compound can be measured by X-ray fluorometry (XRF) or inductively coupled plasma emission spectroscopy (ICP).

The polishing liquid of the embodiment contains a dispersion medium for dissolving or dispersing the permanganate ions, weak acid, and soluble weak acid salt and the optionally added abrasive and specific inorganic compound. Examples of dispersion media suitable to ensure the improving effect of the addition of a weak acid and its soluble salt on the polishing rate include water, water soluble organic solvents, such as alcohols and ketones, and mixtures thereof. The content of the dispersion medium in the polishing liquid is preferably 60 to 99.9 mass %, more preferably 80 to 98 mass %.

The polishing liquid of the embodiment may contain, in addition to the permanganate ions, weak acid, and soluble weak acid salt, any additives other than the optionally added abrasive and specific inorganic compound and dispersing medium. Examples of useful additives are dispersants, pH adjusters, viscosity modifiers, chelating agents, rust inhibitors, and so forth. The total content of the components other than the permanganate salt, weak acid, soluble weak acid salt, abrasive, and specific inorganic compound (except for the dispersion medium) in the polishing liquid is preferably not more than 40 mass %, more preferably 20 mass % or less, even more preferably 10 mass % or less.

The polishing liquid of the embodiment is not limited by the method of preparation and may be prepared by appropriately mixing the permanganate ions, the weak acid and its soluble salt, and, if necessary, the abrasive, inorganic compound, and dispersion medium. The polishing liquid may be formulated in a two- or more-pack system. The two or more packs are formulated as appropriate so that a polishing liquid prepared therefrom may provide sufficient polishing performance. In such a divided package system, it is preferred for the permanganate ions and the weak acid and soluble salt thereof be packaged in the same pack with a view to preventing deterioration by permanganate ion decomposition during long-term storage.

The method for producing a polished substrate according to the invention will next be described. The method of the invention is to provide a polished surface by polishing a substrate using the polishing liquid of the invention. The method of the invention is suitably applied to polishing a hard material with a Mohs hardness of 8 or higher. “Mohs hardness” is a numerical scratch resistance of minerals relative to reference minerals with assigned rankings 1 to 10 in ascending order of hardness: 1, talc; 2, gypsum; 3, calcite; 4, fluorite; 5, apatite; 6, orthoclase; 7, quartz; 8, topaz; 9, corundum; and 10, diamond. Mohs hardness can be measured using a Mohs scale in a usual manner. Hard materials with a Mohs hardness of 8 or higher are exemplified by silicon carbide, gallium nitride, and diamond. The method for producing a polished substrate of the invention is applicable to, for example, chemical mechanical polishing (CMP) as a final polishing step following lapping of a hard material-based substrate. As used herein, the term “substrate” means an object to be polished, and the term “polished substrate” means an object obtained by polishing.

An embodiment of the method of the invention includes supplying the polishing liquid containing permanganate ions and water to a polishing pad, bringing the surface to be polished of a substrate into contact with the polishing pad, and polishing the surface by relative movement between the substrate and the polishing pad. In the embodiment, the used polishing liquid may be discharged as a waste but is preferably recovered and resupplied to the polishing pad in a recirculation system. The expression “a recirculation system” as used herein does not mean that the recovery and resupply cycle should be repeated more than once, and it suffices that the used polishing liquid be reused once. During the recirculation, the pH may be adjusted by the addition of an acid, etc., but the invention makes it possible to retain the polishing rate with no need to conduct such pH adjustment. The embodiment successfully prevents reduction in polishing rate even in such a recirculation system, thereby to achieve cost reduction without impairing the polishing efficiency. The polishing machine that can be used in the invention is selected from known and available polishers, either single side or double side. The polishing pad may be made of materials commonly used in the art, including nonwoven fabrics, nonwoven fabrics impregnated with resin (e.g., polyurethane or epoxy resin), and suede. The polishing pressure is preferably 10 to 10,000 g/cm², more preferably 50 to 5,000 g/cm², in terms of polishing performance and handling of polishing equipment.

Examples of the substrate to be polished with the polishing liquid of the embodiment include SiC substrates for epitaxial growth, SiC substrates or epitaxial SiC film on SiC substrates, sintered SiC substrates, GaN substrates, and diamond substrates.

### EXAMPLES

The invention will now be illustrated in greater detail with reference to Examples, but it should be understood that the invention is not deemed to be limited thereto. Unless otherwise noted, all the percents are by mass.

### Comparative Examples 1 and 2 and Example 1

Pure water, potassium permanganate (KMnO₄), acetic acid, and sodium acetate were mixed to prepare a polishing liquid having the permanganate ion, acetic acid, and sodium acetate concentrations shown in Table 1 below. The pH (at 25° C.) of the polishing liquid before commencement of polishing was measured as an initial pH value, and the results are shown in Table 1. The buffering capacity of the polishing liquid, being defined to be the amount (mL) of a 0.1 mol/L aqueous solution of sodium hydroxide necessary to raise the pH of 100 mL of the polishing liquid having been adjusted to pH 3.0 to 4.0 at 25° C. by 0.5, was measured. The pH adjustment of the polishing liquid to be tested for buffering capacity was done by the addition of a 0.1 mol/L aqueous sodium hydroxide solution when the pH of the polishing liquid was lower than 3.0, or by the addition of a 0.05 mol/L diluted sulfuric acid when it was higher than 4.0. The adjusted pH of the polishing liquid to be tested for buffering capacity and the results of buffering capacity testing are shown in Table 1. The pH measurement was made using a pH electrode 9615S-10D from Horiba (hereinafter the same).

TABLE 1

| | | | | | | | | Polishing | Total | Polishing |
|---|---|---|---|---|---|---|---|---|---|---|
| | | | Acetic | Na | | Buffering | Adjusted | Rate | Removal | Rate |
| | | | Acid | Acetate | Initial pH | Capacity | pH | (initial) | (24 h) | Reduction |
| | Abrasive | MnO₄⁻ | (mol/L) | (mol/L) | (25° C.) | (mL) | (25° C.) | (μm/h) | (μm) | (8 h) (%) |
| Compara. | none | 2.1% | — | — | 9.02 | 0.60 | 3.52 | 0.29 | 4.66 | 23 |
| Example 1 | | | | | | | | | | |
| Compara. | none | 2.1% | 0.021 | — | 3.17 | 1.90 | 3.17 | 0.66 | 5.03 | 72 |
| Example 2 | | | | | | | | | | |
| Example 1 | none | 2.1% | 0.021 | 0.0025 | 3.59 | 3.67 | 3.59 | 0.58 | 8.47 | 3.5 |

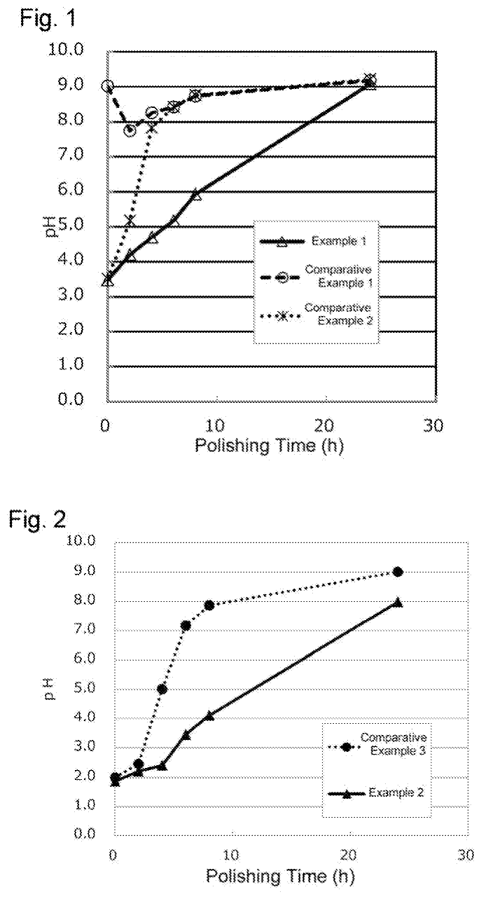

The polishing liquids of Comparative Examples 1 and 2 and Example 1 were each tested for polishing performance to determine the polishing rate with time from the start up to 24 hours. The initial polishing rate (after 2 hours from the start), the total removal in thickness after 24 hours from the start, and the percentage reduction of polishing rate after 8 hours from the start to the initial polishing rate are shown in Table 1. The pH values at 25° C. of the polishing liquid at 2, 4, 6, 8, and 24 hours from the start are shown in FIG. 1.

### Polishing Test:

Polishing was performed using each of the polishing liquids in accordance with the following procedures. A 3-inch lapped 4H-SiC substrate with an off-angle of 4° was used as a substrate. The Si-face of the substrate was polished. A single side polisher BC-15 from MAT Inc. with a polishing pad SUBA#600 from Nitta Haas attached to a platen was used. The polishing conditions were: rotation speed of platen, 60 rpm; platen peripheral velocity, 7163 cm/min; rotation speed of carrier, 60 rpm; carrier peripheral velocity, 961 cm/min; polishing pressure, 210 g/cm²; and slurry feed rate, 200 mL/min. 1.0 L of the polishing liquid was repeatedly reused as described above. The polishing rate (μm/h) was calculated from the difference in mass of the substrate between before and after polish and the density of SiC (3.10 g/cm³).

The total removal in thickness after 24-hour polishing was obtained through the same calculation.

As is apparent from the results in FIG. 1, the polishing liquid of Example 1 shows an almost constant rate of pH increase with time, proving able to have its hydrogen ion concentration under control. The polishing liquid of Example 1 is able to retain a satisfactory polishing rate for a longer period of time than the conventional polishing liquid containing permanganate ions but neither containing a weak acid nor its salt (Comparative Example 1) and the polishing liquid containing permanganate ions and acetic acid but not containing a weak acid salt (Comparative Example 2), as proved by the percentage reduction of polishing rate after 8-hour polishing. Therefore, the polishing liquid of the invention makes it feasible to reduce the frequency of replacing the used polishing liquid by a fresh one in polishing operation of hard materials, such as silicon carbide and gallium nitride, thus effectively improving the productivity.

### Comparative Example 3 and Example 2

Pure water, potassium permanganate (KMnO₄), cerium (IV) ammonium nitrate ((NH₄)₂[Ce(NO₃)₆], hereinafter abbreviated as CAN), acetic acid, and sodium acetate were mixed to prepare a polishing liquid having the permanganate ion, acetic acid, sodium acetate, and CAN concentrations shown in Table 2 below. The pH (at 25° C.) of the polishing liquid before commencement of polishing was measured as an initial pH value, and the results are shown in Table 2. The buffering capacity of the polishing liquid was measured. The results of the buffering capacity measurement and the adjusted pH of the polishing liquid being tested are also shown in Table 2. When CAN was added to a 1.0% aqueous solution of the permanganate in a concentration of 1.0%, the resulting solution exhibited a redox potential of 1291 mV at 25° C. The redox potential of the 1.0% aqueous solution of the permanganate before the addition of CAN was 770 mV at 25° C. was 770 mV. The redox potential measurement was taken with ORP electrode 9300-10D from Horiba immersed in each solution at 25° C.

TABLE 2

| | | | | | | | | | Polishing | Total | Polishing |
|---|---|---|---|---|---|---|---|---|---|---|---|
| | | | Acetic | Na | | | Buffering | Adjusted | Rate | Removal | Rate |
| | | | Acid | Acetate | | Initial pH | Capacity | pH | (initial) | (24 h) | Reduction |
| | Abrasive | MnO₄⁻ | (mol/L) | (mol/L) | CAN | (25° C.) | (mL) | (25° C.) | (μm/h) | (μm) | (8 h) (%) |
| Compara. | none | 2.1% | — | — | 0.24% | 1.89 | 0.59 | 3.50 | 0.87 | 5.98 | 59.0 |
| Example 3 | | | | | | | | | | | |
| Example 2 | none | 2.1% | 0.021 | 0.0025 | 0.24% | 1.93 | 2.74 | 3.49 | 1.05 | 12.33 | 48.3 |

The polishing liquids of Comparative Example 3 and Example 2 were each tested for polishing performance to determine the polishing rate in the same manner as in Example 1. The initial polishing rate (after 2 hours from the start), the total removal in thickness after 24-hour polishing, and the percentage reduction of polishing rate after 8-hour polishing to the initial polishing rate are shown in Table 2. The pH values at 25° C. of the polishing liquid at 2, 4, 6, 8, and 24 hours from the start are shown in FIG. 2.

As is apparent from the results shown in Table 2 and FIG. 2, the polishing liquid of the invention shows an almost constant rate of pH increase with time, proving able to have its hydrogen ion concentration under control even in the presence of a specific inorganic compound serving as an oxidizer in addition to the permanganate ions. The polishing liquid of the invention thus proved able to retain sufficient polishing rates for practical use.

### Comparative Example 4 and Examples 3 and 4

Pure water, potassium permanganate (KMnO₄), silica particles (average particle size D₅₀: 0.34 μm), acetic acid, and sodium acetate were mixed to prepare a polishing liquid having the permanganate ion, acetic acid, sodium acetate, and silica particles concentrations shown in Table 3 below. The pH (at 25° C.) of the polishing liquid before commencement of polishing was measured as an initial pH value, and the results are shown in Table 3. The buffering capacity of the polishing liquid was measured. The results of the buffering capacity measurement and the adjusted pH of the polishing liquid being tested are also shown in Table 3. Before the D₅₀ measurement, the silica particles were dispersed by ultrasonication (30 W) for 3 minutes. The D₅₀ measurement was taken using a laser diffraction/scattering particle size distribution analyzer Microtrac MT3300EX II from MicrotracBEL Corp. under conditions: transmissivity of particle, refractive; shape of particle, non-spherical; particle refractive index, 1.46; and solvent refractive index, 1.333.

TABLE 3

| | | | | | | | | Polishing | Total | Polishing |
|---|---|---|---|---|---|---|---|---|---|---|
| | | | Acetic | Na | | Buffering | Adjusted | Rate | Removal | Rate |
| | | | Acid | Acetate | Initial pH | Capacity | pH | (initial) | (24 h) | Reduction |
| | Abrasive | MnO₄⁻ | (mol/L) | (mol/L) | (25° C.) | (mL) | (25° C.) | (μm/h) | (μm) | (8 h) (%) |
| Compara. | silica | 2.1% | — | — | 8.88 | 0.32 | 3.47 | 0.65 | 4.72 | 77 |
| Example 4 | (0.10%) | | | | | | | | | |
| Example 3 | silica | 2.1% | 0.021 | 0.0025 | 3.64 | 3.89 | 3.64 | 0.63 | 10.26 | 3.2 |
| | (0.10%) | | | | | | | | | |
| Example 4 | silica | 2.1% | 0.00089 | 0.00008 | 4.64 | 0.67 | 4.64 | 0.67 | 7.20 | 49.5 |
| | (0.10%) | | | | | | | | | |

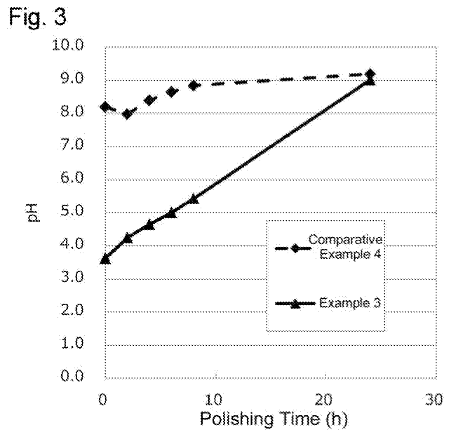

The polishing liquids of Comparative Example 4 and Examples 3 and 4 were each tested for polishing performance to determine the polishing rate in the same manner as in Example 1. The initial polishing rate (2 hours from the start), the total removal in thickness after 24-hour polishing, and the percentage reduction of polishing rate after 8-hour polishing to the initial polishing rate are shown in Table 3. The pH values at 25° C. of the polishing liquid at 2, 4, 6, 8, and 24 hours from the start are shown in FIG. 3.

As is apparent from the results shown in Table 3 and FIG. 3, the polishing liquid of the invention shows almost constant rates in pH increase and polishing rate reduction with time even in the presence of an abrasive. The polishing liquid of the invention thus proves effective in preventing reduction in polishing rate with use for a prolonged period of time.

### INDUSTRIAL APPLICABILITY

The invention provides a polishing liquid for polishing hard materials, such as silicon carbide and gallium nitride, that is prevented from reducing in polishing rate even when used for a prolonged period of time, thereby achieving improved polishing efficiency as compared with existing polishing compositions. The invention also provides a method for producing a polished substrate including using the polishing liquid of the invention.

1. A polishing liquid comprising permanganate ions, a weak acid, and a soluble salt of the weak acid.

2. The polishing liquid according to claim 1, having a pH of 0.5 to 6 at 25° C. before use.

3. The polishing liquid according to claim 1, having a buffering capacity of 0.1 to 100 mL, the buffering capacity being defined to be the amount of a 0.1 mol/L aqueous solution of sodium hydroxide necessary to raise the pH of 100 mL of the polishing liquid adjusted to pH 3.0 to 4.0 at 25° C. by 0.5.

4. The polishing liquid according to claim 1, wherein the weak acid is acetic acid.

5. The polishing liquid according to claim 1, wherein the total amount of the weak acid and its soluble salt in the polishing liquid is 0.001 to 1 mol/L in terms of the total number of moles of the weak acid anion.

6. The polishing liquid according to claim 1, wherein the amount of the soluble salt of the weak acid in the polishing liquid is 0.05 to 20 mol per mole of the weak acid.

7. The polishing liquid according to claim 1, being for polishing silicon carbide.

8. The polishing liquid according to claim 1, being free of an abrasive.

9. The polishing liquid according to claim 1, further comprising a particulate abrasive.

10. The polishing liquid according to claim 9, wherein the particulate abrasive is selected from the group consisting of alumina, silica, manganese oxide, cerium oxide, zirconium oxide, iron oxide, silicon carbide, and diamond.

11. A method for producing a polished substrate comprising using the polishing liquid according to claim 1.
